(19) United States
(12) Patent Application Publication
(10) Pub. No.: US 2016/0149068 A1
(43) Pub. Date: May 26, 2016

(54) MULTI-JUNCTION SOLAR CELL

(71) Applicant: COMMISSARIAT À L'ÉNERGIE ATOMIQUE ET AUX ÉNERGIES ALTERNATIVES, Paris (FR)

(72) Inventors: Mathieu BAUDRIT, Chambery (FR); Thomas SIGNAMARCHEIX, Grenoble (FR)

(73) Assignee: Commissariat a I'energie atomique et aux energies alternatives, Paris (FR)

(21) Appl. No.: 14/899,754

(22) PCT Filed: Jun. 16, 2014
(86) PCT No.: PCT/EP14/62522

§ 371 Date: Dec. 18, 2015

(30) Foreign Application Priority Data
Jun. 18, 2013 (FR) 13 55735

(51) Int. Cl. H01L 31/0725; H01L 31/18; H01L 31/0224

(52) U.S. Cl. CPC H01L 31/0725; H01L 31/022425; H01L 31/1876

(57) ABSTRACT

A solar cell including: a stack of at least two sub-cells, a tunnel diode, including first and second superposed layers that are highly doped with opposite conductivity types, being interposed between two adjacent sub-cells; a first electrode and a second electrode respectively in contact with one and other of faces positioned at the ends of the stack; and, for at least one tunnel diode, a third electrode and a fourth electrode in electrical contact respectively with the first layer and the second layer of the tunnel diode.

### TECHNICAL FIELD

The present invention relates to a multi-junction solar cell and a method for manufacturing such a solar cell. The present invention relates more specifically to a multi-junction solar cell intended to be used for photovoltaic applications.

### STATE OF THE PRIOR ART

In the field of photovoltaic solar cells with high solar energy conversion efficiency, it is sought to optimise the collection of the photons of the incident solar spectrum.

Solar cells known as “multi-junction” cells have been proposed. Multi-junction solar cells include a stack of several sub-cells, where each sub-cell consists of a stack of different semiconducting layers forming a PN junction. The PN junctions of each sub-cell are formed such that each has a different band-gap energy. Each sub-cell thus absorbs a reduced portion of the solar spectrum but with high efficiency. This results in an increased overall efficiency of such a solar cell compared to a solar cell with a single silicon junction.

Multi-junction solar cells are commonly formed by epitaxial growth of the different layers constituting the different sub-cells on a given substrate. Multi-junction solar cells formed by such a method are called “monolithic” cells.

In a monolithic multi-junction solar cell in operation, a potential difference is applied between two electrodes positioned either side of the stack of the different sub-cells. The sub-cells are connected in series through tunnel diodes or tunnel junctions positioned between two adjacent sub-cells. Since the sub-cells are connected in series the sub-cell absorbing the least energy of the incident spectrum, and therefore supplying the least current, limits the other cells to this current value. The maximum power supplied by a monolithic multi-junction solar cell is equal to the minimum of the currents delivered by the different sub-cells by the voltage at the terminals of the multi-junction cell (equal to the sum of the voltages at the terminals of the sub-cells), and not to the sum of the maximum power outputs supplied by each sub-cell.

One advantage of monolithic multi-junction solar cells is that they are manufactured by methods which are simple to implement and well controlled. This results in a high production capacity and multi-junction solar cells of good quality.

One disadvantage of monolithic multi-junction solar cells relates to the fact that the different sub-cells are connected in series. This means that the optimum operation of such solar cells, enabling the maximum power output supplied by the solar cell to be obtained, is not equal to the optimum operation of each sub-cell. In addition, if one of the sub-cells has varied performance whilst in operation, for example due to a real solar spectrum which does not accord with the solar spectrum used for the design of the solar cell, or due to an external element such as a concentration lens, or due to a degradation of its characteristics, this leads to a reduction of the solar cell's overall performance. This results in reduced efficiency of such solar cells.

To increase the power delivered by a monolithic multi-junction solar cell, one solution consists in manufacturing the cell such that each sub-cell delivers the same current for a given incident spectrum. The term “current alignment” of the sub-cells is used. However, this results in a more complex method of manufacture of the solar cell. In addition, current alignment is valid only for the incident spectrum chosen for optimisation of the solar cell.

Furthermore, instead of being formed in a monolithic fashion, multi-junction solar cells can be formed by a method of mechanical assembly of the different sub-cells. Such multi-junction solar cells are called “multi-terminal” cells. Each sub-cell is formed independently of the other sub-cells, for example by epitaxial growth on a substrate. Electrodes, for example conductive pads, are formed either side of each sub-cell. The sub-cells are then assembled mechanically with one another. In a multi-terminal, multi-junction solar cell in operation, a potential difference is applied between the two electrodes of each sub-cell. The electrical operation of each sub-cell is independent of that of the other sub-cells.

One advantage of multi-terminal, multi-junction solar cells is that the operation of each sub-cell can be optimised individually. The maximum power supplied by a multi-terminal, multi-junction solar cell is equal to the sum of the maximum power outputs supplied by each sub-cell. In addition, a degradation of the performance of one of the sub-cells does not lead to a degradation of the performance of the other sub-cells. This results in a high efficiency of such solar cells.

Another advantage of multi-terminal, multi-junction solar cells is that current alignment of each sub-cell for a given incident spectrum is not necessary.

Conversely, such a method of mechanical assembly of the sub-cells requires satisfactory control of the alignment of the sub-cells, such that the sub-cells of the upper levels do not cause a shadow effect on the sub-cells of the lower levels. Indeed, if the conductive pads forming the electrodes of the different sub-cells are not satisfactorily aligned to one another this leads to a reduction of the quantity of photons absorbed by the underlying sub-cells, i.e. the sub-cells positioned under the sub-cell one of the faces of which constitutes the front face of the mechanical assembly.

One disadvantage of multi-terminal, multi-junction solar cells is the complexity of the existing manufacturing methods. In addition, since the sub-cells are manufactured individually on different substrates, this results in a high manufacturing cost.

One example of a two-junction solar cell formed by epitaxial growth is described in patent application US 2010/0089440. According to an embodiment described in this document the solar cell includes three terminals. A first terminal and a second terminal are connected respectively to both the two sub-cells, and a third terminal is connected to a conductive layer positioned between the two sub-cells. In such a solar cell a potential difference can be applied either between the first and second terminals, or between the first and third terminals, or between the second and third terminals. If a potential difference is applied between the first terminal and the second terminal the solar cell operates as a conventional monolithic two-junction solar cell, where the two sub-cells are connected in series. The satisfactory operation of each sub-cell independently of the other sub-cell can also be checked by applying a potential difference between the first terminal and the third terminal, or between the second terminal and the third terminal. This allows a check to be made that the currents supplied by the two sub-cells are equal, for example. One disadvantage of such a two-junction solar cell is that the two sub-cells cannot be brought into operation simultaneously independently of one another.

The problem of producing, by a manufacturing method which is simple to implement, a multi-junction solar cell in which the different sub-cells can be connected simultaneously independently of one another is therefore posed.

The problem of producing a multi-junction solar cell with optimum efficiency is also posed.

### DESCRIPTION OF THE INVENTION

The present invention seeks in particular to resolve these problems.

The present invention relates to a solar cell including a stack of at least two sub-cells, where a tunnel diode, including first and second superposed layers which are doped with opposite conductivity types, is interposed between two adjacent sub-cells. A first electrode and a second electrode are respectively in contact with one face and the other face positioned at the ends of the stack. For at least one tunnel diode, a third electrode and a fourth electrode are respectively in electrical contact with the first layer and the second layer of the tunnel diode.

According to one embodiment of the present invention, for each tunnel diode a third electrode and a fourth electrode are respectively in electrical contact with the first layer and the second layer of the tunnel diode. The third and fourth electrodes are used as additional electrodes enabling each sub-cell to be polarised independently of the other sub-cells.

According to one embodiment of the present invention, the first electrode is in contact with the face of the stack intended to be exposed to light radiation, and partially covers this face, and the second electrode is in contact with the face of the stack opposite the said face intended to be exposed to light radiation, and fully covers this face.

For said at least one tunnel diode, the third and fourth electrodes may be positioned:
on the first and second layers of the tunnel diode on the side of the face of the stack intended to be exposed to light radiation;
or on the first and second layers of the tunnel diode on the side of the face of the stack opposite the said face intended to be exposed to light radiation.

According to one embodiment of the present invention, at least one tunnel diode also includes a first and a second conductive barrier layer, positioned either side of the stack of the first and second layers, respectively in contact with the first layer and the second layer. The third electrode associated with this tunnel diode may be in direct contact with the first barrier layer and/or the fourth electrode associated with this tunnel diode may be in direct contact with the second barrier layer.

According to one embodiment of the present invention, at least two adjacent sub-cells are separated by a tunnel diode the first layer and the second layer of which are not in contact with any electrode, where the said at least two adjacent sub-cells form an assembly of sub-cells intended to be connected in series.

One advantage of a multi-junction solar cell of the type described above is that each sub-cell can be associated with two electrodes, enabling it to be polarised independently of the other sub-cells. In addition, the different sub-cells can be polarised independently of one another and simultaneously.

Another advantage of such a multi-junction solar cell is that it can operate either as a monolithic two-junction solar cell (in monolithic mode), or as a multi-terminal two-junction solar cell (in multi-terminal mode).

Another advantage of such a multi-junction solar cell is related to the fact that the operation of each of the sub-cells can be optimised individually, and therefore the overall efficiency of the solar cell can be maximised.

Another advantage of such a multi-junction solar cell is that it can be manufactured by a manufacturing method which is simple to implement, of the monolithic type.

The present invention also relates to a method for forming a solar cell, including the following steps consisting in a) forming a stack of at least two sub-cells, a tunnel diode, including first and second superposed layers doped with opposite conductivity types, being interposed between two adjacent sub-cells; then, in any order, b) forming a first electrode and a second electrode respectively in contact with the face of the stack intended to be exposed to the light radiation, and with the face of the stack opposite the said face intended to be exposed to the light radiation; and c) for at least one tunnel diode, forming a third electrode and a fourth electrode respectively in electrical contact with the first layer and the second layer of the tunnel diode.

According to one embodiment of the present invention, in step c), for each tunnel diode, a third electrode and a fourth electrode, in electrical contact respectively with the first layer and the second layer of the tunnel diode, are formed.

In step a), the stack of at least two sub-cells with interposition of a tunnel diode may be formed by epitaxial growth.

The above method may also include, between steps a) and c), a step of formation, for at least one tunnel diode, of a first opening and of a second opening, so as to expose respectively a portion of the first layer and a portion of the second layer of the tunnel diode.

According to one embodiment of the present invention, the step of formation, for at least one tunnel diode, of the first and second openings, is accomplished before step b) of formation of the first and second electrodes.

The first and second openings may be formed by an anisotropic etching method, for example by plasma etching, or by an isotropic etching method, for example by wet chemical etching.

The first and second openings may be formed from the face of the stack intended to be exposed to the light radiation, called the front face.

As a variant, they may be formed from the face of the stack called the rear face, opposite the said face intended to be exposed to the light radiation. According to another variant they may be formed from the front face and from the rear face.

One advantage of a method for forming a multi-junction solar cell of the type described above is that it is simple to implement. Indeed, such a method uses steps commonly used in the course of methods for manufacturing microelectronic components.

The present invention also relates to a method of using a solar cell of the type described above, including the following steps consisting in a) measuring the current delivered by each sub-cell or assembly of sub-cells connected in series; b) comparing the currents delivered by the different sub-cells or assemblies of sub-cells; c) if the currents delivered by the different sub-cells or assemblies of sub-cells are equal, connecting the solar cell such that it operates in monolithic mode; c′) if the currents delivered by the different sub-cells or assemblies of sub-cells are not all equal, connecting the solar cell such that it operates in multi-terminal mode.

According to one embodiment of the present invention, for each tunnel diode of which the first layer and the second layer are respectively in contact with a third electrode and a fourth electrode, in step c) the third and fourth electrodes are not connected and the tunnel diode is electrically conductive.

In step c) a potential difference may be applied between the first and second electrodes such that the power delivered by the solar cell is maximum.

According to one embodiment of the present invention, for each tunnel diode of which the first layer and the second layer are respectively in contact with a third electrode and a fourth electrode, in step c′) a potential difference is applied between the third and fourth electrodes such that the current flowing through the tunnel diode is minimal.

According to one embodiment of the present invention, in step c′), for each tunnel diode of which the first layer and the second layer are respectively in contact with a third electrode and a fourth electrode, it is sought to determine the potential difference to be applied between the third and fourth electrodes for the current flowing through the tunnel diode to be minimal.

According to one embodiment of the present invention, in step c′), for each sub-cell or assembly of sub-cells connected in series, it is sought to determine the optimum polarisation of the sub-cell or of the assembly of sub-cells for the power delivered by the sub-cell or by the assembly of sub-cells to be maximum. Each electrode of the solar cell may then be polarised such that each sub-cell or assembly of sub-cells is polarised at the said optimum polarisation.

The method of using a solar cell of the type described above may also include a step d) consisting in repeating steps a) to c) or steps a) to c′). By this means, if the current alignment of the sub-cells is degraded whilst using the solar cell, for example due to a degradation of the characteristics of one of the sub-cells, or due to a degradation of an element external to the solar cell, such as a concentration lens, or due to a real solar spectrum not in accordance with the solar spectrum used for the design of the solar cell, the solar cell changes from monolithic operating mode to multi-terminal operating mode. This results in an optimised efficiency of the solar cell.

According to one embodiment of the present invention, with each repetition of step c′), it is also possible to seek to determine once again, for each tunnel diode of which the first layer and the second layer are respectively in contact with a third electrode and a fourth electrode, the potential difference to be applied between the third and fourth electrodes for the current flowing through the tunnel diode to be minimal.

With each repetition of step c′), it is possible to seek to determine once again the optimum polarisation of each sub-cell or assembly of sub-cells.

Step d) may be repeated at regular time intervals.

One advantage of a method of using a multi-junction solar cell of the type described above is that the power delivered by the solar cell can be optimised even when the sub-cells do not all deliver the same current. This results in an optimum efficiency of the solar cell.

Another advantage of such a method of using a multi-junction solar cell is that if the current alignment of the sub-cells is degraded, for example due to a degradation of the performance characteristics of one of the sub-cells, or due to reasons external to the solar cell, or due to a real solar spectrum not in accordance with the solar spectrum used for the design of the solar cell, this has no impact on the other sub-cells since the sub-cells are then connected in multi-terminal mode.

Another advantage of such a method of using a multi-junction solar cell is that it is not necessary to manufacture the solar cell such that all the sub-cells deliver the same current.

The present invention also relates to a method of using a solar cell of the type described above, including the following steps consisting in a) measuring the current delivered by each sub-cell; b) comparing the currents delivered by the different sub-cells; c) if the currents delivered by the different sub-cells are equal, connecting the solar cell such that it operates in monolithic mode; c′) if the currents delivered by the different sub-cells are not all equal, connecting the adjacent sub-cells which deliver the same current in monolithic mode, and connecting the other sub-cells in multi-terminal mode.

The present invention also relates to a device for testing a solar cell of the type described above, including means for measuring or determining the current delivered by each sub-cell or assembly of sub-cells connected in series, and means for comparing the currents delivered by the different sub-cells or assemblies of sub-cells. Means also enable the solar cell to be connected such that it operates in monolithic mode if the currents delivered by the different sub-cells or assemblies of sub-cells are equal, and such that it operates in multi-terminal mode if the currents delivered by the different sub-cells or assemblies of sub-cells are not all equal.

According to one embodiment of the present invention, this test device also includes first analysis means intended to seek, for each tunnel diode, the potential difference to be applied between the third and fourth electrodes for the current flowing through the tunnel diode to be minimal.

It may possibly also include computation means intended to calculate the power delivered by each sub-cell or assembly of sub-cells as a function of its polarisation.

Second analysis means may be provided, to seek, for each sub-cell or assembly of sub-cells, the optimum polarisation of the sub-cell or of the assembly of sub-cells for which the power delivered by the sub-cell or by the assembly of sub-cells is maximum.

The test device may also include means for calculating or determining the potential to be applied to each electrode of the solar cell, such that the current flowing through each tunnel diode is minimum, and such that the power delivered by each sub-cell or assembly of sub-cells is maximum.

According to one embodiment of the present invention, the test device may include a computer or a calculator or a measuring system enabling calculations or measurements of potential differences, and/or of potentials and/or of power outputs presented above to be made.

### BRIEF DESCRIPTION OF THE ILLUSTRATIONS

Other characteristics and advantages of the invention will be shown more clearly on reading the following description and with reference to the appended illustrations, which are given as illustrations only, and are in no way restrictive.

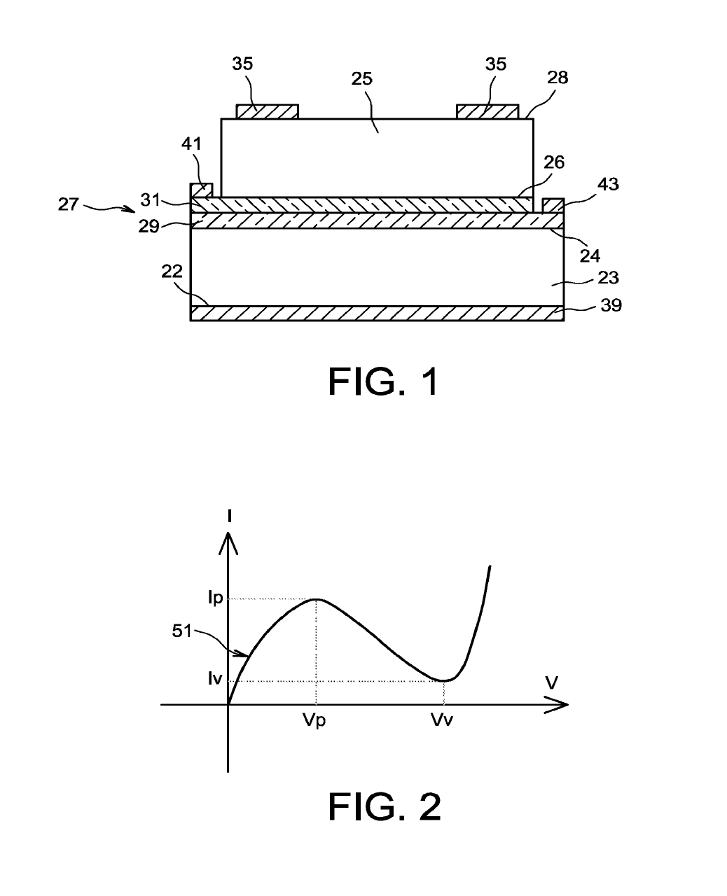

FIG. 1 is a section view representing schematically an embodiment of a two-junction solar cell according to the invention.

FIG. 2 is an usual current-voltage characteristic curve of a tunnel diode.

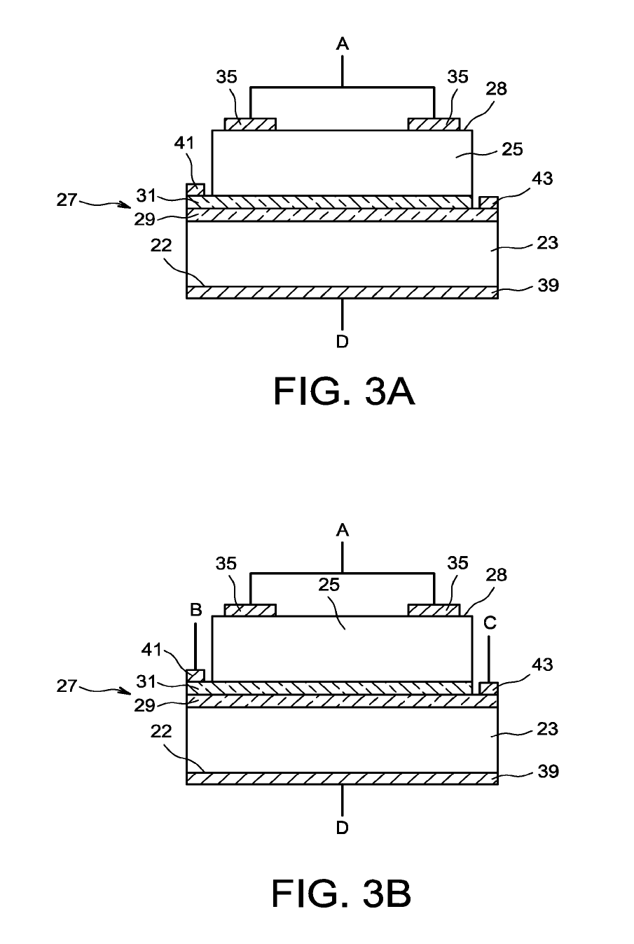

FIGS. 3A and 3B are section views representing schematically a two-junction solar cell according to the invention connected respectively for operation in monolithic mode and for operation in multi-terminal mode.

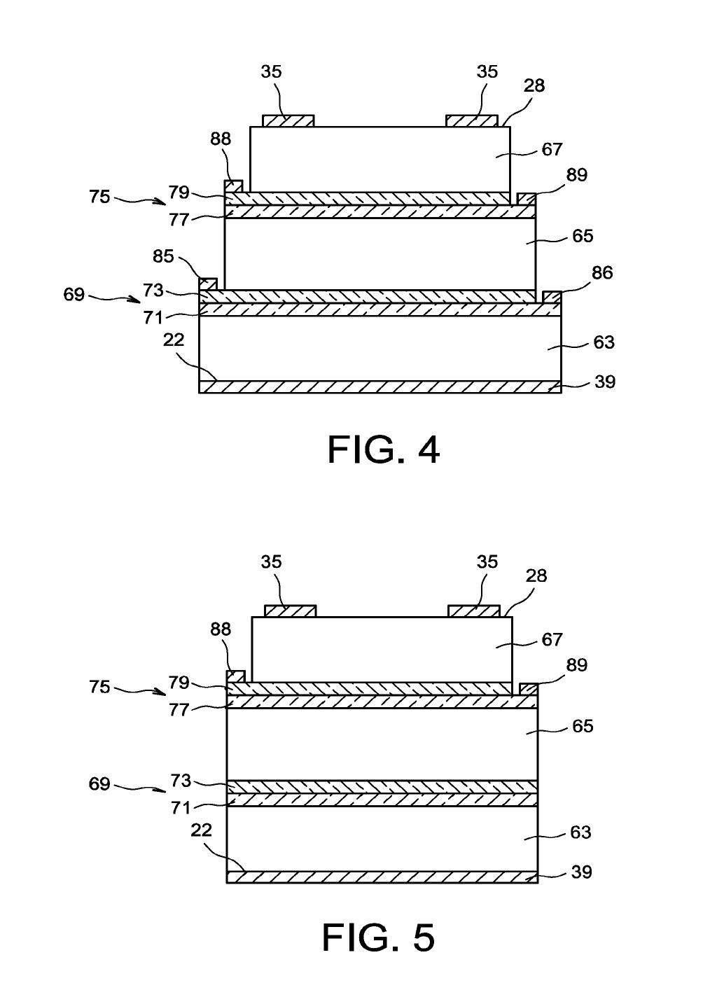

FIG. 4 is a section view representing schematically an embodiment of a three-junction solar cell according to the invention.

FIG. 5 is a section view representing schematically a variant of a three-junction solar cell according to the invention.

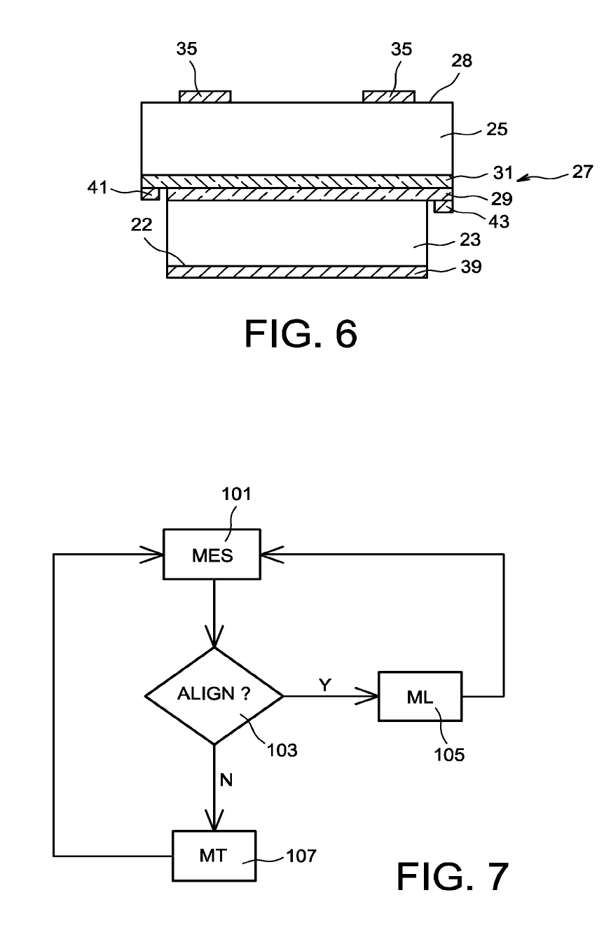

FIG. 6 is a section view representing schematically a variant of a two-junction solar cell according to the invention.

FIG. 7 is a diagram illustrating a method of using a multi-junction solar cell according to the invention.

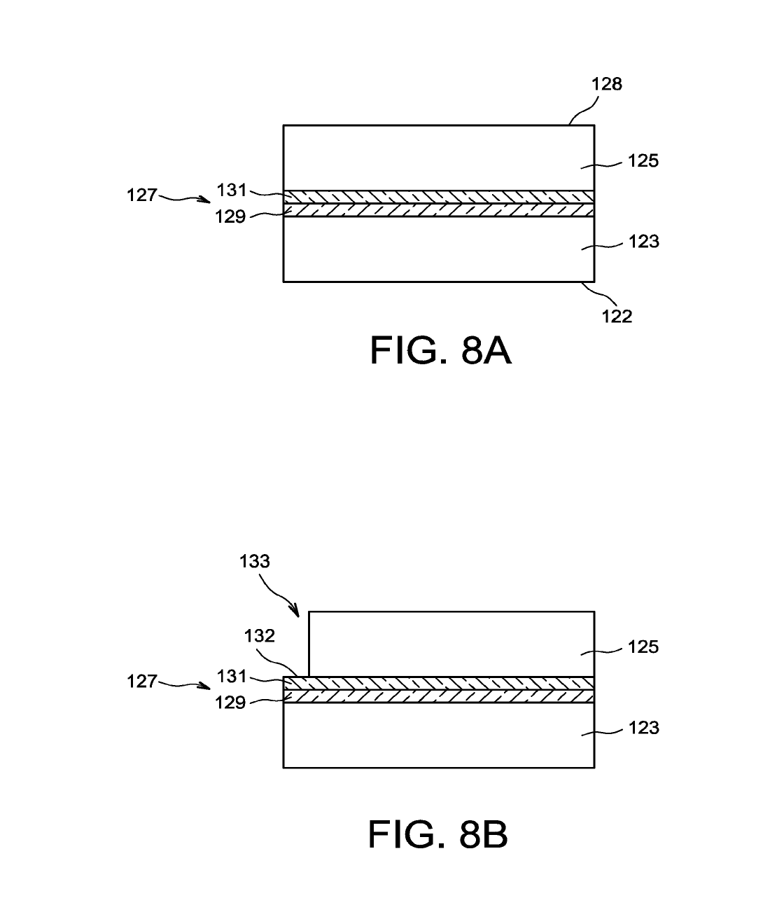

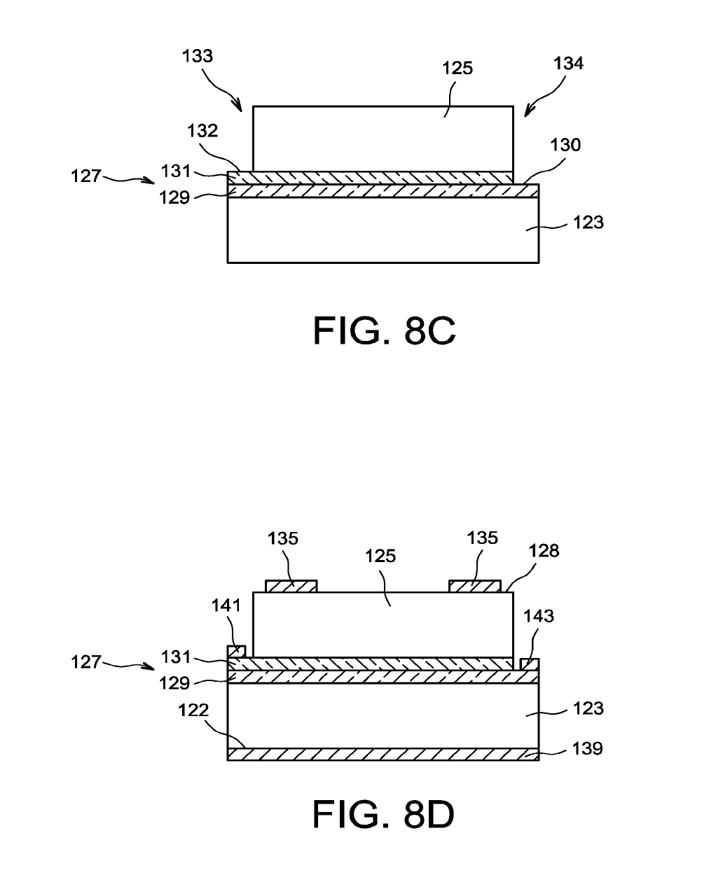

FIGS. 8A to 8D are section views representing schematically successive steps of a method of manufacturing a two-junction solar cell according to the invention.

Identical, similar or equivalent portions of the various figures have the same numerical references, to make it easier to go from one figure to another.

The various portions represented in the figures are not necessarily represented at a uniform scale, in order to make the figures more readable.

### DETAILED DESCRIPTION OF PARTICULAR EMBODIMENTS

The inventors propose to produce a multi-junction solar cell using an integration called “monolithic” integration, and to use layers doped with opposite conductivity types of the tunnel diodes positioned between the different sub-cells, such that the different sub-cells can be connected independently of one another.

FIG. 1 is a section view representing schematically an embodiment of a two-junction solar cell according to the invention.

The solar cell includes a stack of two sub-cells 23 and 25, where a tunnel diode 27 is interposed between sub-cells 23 and 25. Each sub-cell 23, 25 consists of a stack of semiconducting layers forming a PN junction.

Sub-cell 23 includes two main faces 22 and 24, and sub-cell 25 includes two main faces 26 and 28. Face 22 and face 28 are positioned at the ends of the stack. In this embodiment as in all embodiments described below, face 28 of the solar cell is preferably the face which is intended to be exposed to the incident light radiation, called the front face, and face 22 is opposite the face intended to be exposed to the light radiation, called the rear face. In this case, sub-cells 23, 25 are formed such that the band-gap energy of sub-cell 25 is higher than that of sub-cell 23. The incident radiation which is not absorbed by sub-cell 25 is thus transmitted to sub-cell 23.

Tunnel diode 27 includes at least one stack of two superposed semiconducting layers 29 and 31 which are very highly doped, for example with a doping level higher than 10¹⁹ cm⁻³ and with opposite conductivity types, forming a tunnel junction. Tunnel diode 27 is produced so that it has a high optical transmittance factor, to minimise the current losses due to the absorption of the radiation by the layers of the tunnel diode. If each sub-cell 23, 25 includes a stack of P-type semiconducting layers covered with N-type semiconducting layers, layers 29 and 31 of tunnel diode 27 are respectively of the N type and of the P type.

As an example, layers 29 and 31 of tunnel diode 27 are made of GaAs and are between 5 and 30 nm thick, for example of the order of 15 nm thick. Layer 29 is, for example, N-doped, for example with a doping level of between 1.10¹⁹ and 8.10¹⁹ cm⁻³, for example of the order of 3.10¹⁹ cm⁻³. Layer 31 is then P-doped, for example with a doping level of between 1.10¹⁹ and 8.10¹⁹ cm⁻³, for example of the order of 5.10¹⁹ cm⁻³.

An electrode (or conductive contact) 35 is in contact with face 28, and an electrode (or conductive contact) 39 is in contact with face 22. Contacts 35 and 39 are intended to polarise respectively faces 28 and 22 of the solar cell. In addition, contact 35 constitutes a first electrode to polarise sub-cell 25, and contact 39 constitutes a first electrode to polarise sub-cell 23.

Contact 35 may be formed from a continuous conductive layer fully covering face 28. In this case, it is preferably made of an optically transparent conductive material. According to an alternative, contact 35 covers face 28 only partly. This results in an improved absorption of the light radiation by sub-cell 25 compared to the case wherein contact 35 is formed from a continuous conductive layer fully covering face 28. If contact 35 covers face 28 only partly it may be made of a non-optically transparent conductive material. Contact 35 may be formed from conductive tracks positioned at some distance from one another, as represented in FIG. 1, for example conductive lines which are parallel to one another. Contact 39 is advantageously formed from a continuous conductive layer fully covering face 22. This results in improved contact with sub-cell 23, and therefore an optimisation of the collected current.

The inventors propose to use layers 31 and 29 of tunnel diode 27 as electrically conductive layers in order to polarise respectively sub-cell 25 and sub-cell 23.

An electrode (or conductive contact) 41 is in contact with layer 31 of tunnel diode 27, and an electrode (or conductive contact) 43 is in contact with layer 29 of tunnel diode 27. Each of contacts 41 and 43 is electrically insulated from the other layers of the stack constituting the solar cell. Contacts 41 and 43 are, for example, positioned on the side of face 28 or, in other words, in contact with the upper face of corresponding layer 31, 29. By definition, the upper face of layer 31 corresponds to the face in contact with sub-cell 25 and the upper face of layer 29 corresponds to the face in contact with layer 31. Each of layers 31 and 29 also includes a lower face opposite the corresponding upper face as defined above. Contacts 41 and 43 are intended to polarise respectively layers 31 and 29 of tunnel diode 27.

Sub-cell 25 can thus be polarised by electrodes 35 and 41, and sub-cell 23 can be polarised by electrodes 39 and 43.

Contacts 41 and 43 are, for example, positioned at the lateral ends of the solar cell, as represented in FIG. 1. Layer 31 of tunnel diode 27 preferably covers entirely face 26 of sub-cell 25 in order to enable all the carriers generated by sub-cell 25 to be collected by electrode 41. Layers 31 and 29 of the tunnel diode, which are very highly doped, allow a mechanism for lateral conduction of the carriers. Thus, wherever a gathering of a carrier may be in layer 31, the carrier will generate a current which, by lateral conduction, will be able to be collected by electrode 41.

Contacts 35, 39, 41 and 43 are preferably made of an alloy of metal materials. Contact 35 may possibly be manufactured from an optically transparent conductive material, for example ITO (Indium Tin Oxide), and/or contact 39 may be made of a doped semiconductor material.

According to a variant of the solar cell illustrated in FIG. 1, tunnel diode 27 may also include conductive barrier layers positioned either side of the tunnel junction consisting of layers 29 and 31. The barrier layer positioned between sub-cell 25 and layer 31 is called the upper barrier layer, and the barrier layer positioned between sub-cell 23 and layer 29 is called the lower barrier layer. These barrier layers enable diffusion of the doping elements from the tunnel junction to sub-cells 23 and 25 to be prevented. Electrodes 41 and 43 are preferably in direct contact respectively with layers 31 and 29 of the tunnel junction. Since the barrier layers are conductive, electrodes 41 and 43 may possibly be in direct contact respectively with the upper and lower barrier layers. Nevertheless, according to the inventors, the electrical contacts are improved if each of electrodes 41, 43 is in direct contact with corresponding layer 31, 29, rather than in direct contact with the corresponding barrier layer. One of electrodes 41, 43 may possibly be in direct contact with corresponding layer 31, 29, and the other electrode may be in direct contact with the corresponding barrier layer.

One advantage of a solar cell of the type illustrated in FIG. 1 is that each sub-cell is associated with two electrodes which are dedicated to it, enabling it to be polarised independently of the other sub-cell. In addition, the two sub-cells can be polarised independently of one another and simultaneously.

The operation of a solar cell of the type illustrated in FIG. 1 is described below in relation with FIGS. 2 and 3A-3B.

FIG. 2 illustrates an usual current-voltage characteristic curve I(V) representing current I flowing through a tunnel diode as a function of voltage V at its terminals. Characteristic curve I(V) includes a current peak of value Ip for polarisation Vp and a minimum courant Iv for polarisation Vv. Points Ip(Vp) and Iv(Vv) are notably determined by the materials of highly doped layers N and P of the tunnel diode, by their doping level and by their thickness. The solar cell illustrated in FIG. 1 is preferably manufactured such that current Ip of tunnel diode 27 is greater than current I delivered by the solar cell under nominal operating conditions, and flowing through the tunnel diode. The usual regime of operating the tunnel diode corresponds to portion 51 of characteristic curve I(V), i.e. to the points of current I lower than Ip and of voltage V lower than Vp. To find polarisation point Vv of the tunnel diode, a potential difference is applied between electrodes 41 and 43 of the tunnel diode. This potential difference is varied until a polarisation Vv is found for which the current flowing through the tunnel diode is minimal (equal to Iv).

In the case of a tunnel diode 27 including a layer 29 made of GaAs, with a thickness of around 20 nm, N-doped with a doping level of the order of 3.10¹⁹ cm⁻³, and a layer 31 made of GaAs, with a thickness of around 20 nm, P-doped with a doping level of the order of 5.10¹⁹ cm⁻³, polarisation Vv is, for example, of the order of 0.8 V.

FIG. 3A is a section view illustrating schematically a two-junction solar cell of the type described in relation with FIG. 1 in the case wherein the two sub-cells 23, 25 are connected in series. In this case the term used is operation in “monolithic” mode.

In the monolithic operating mode a potential difference is applied between electrodes 35(A) and 39(D) respectively in contact with faces 28 and 22. Electrodes 41 and 43 respectively in contact with layers 31 and 29 of the tunnel diode 27 are not connected. Sub-cells 23, 25 and tunnel diode 27 are connected in series. Tunnel diode 27 is traversed by a current equal to the minimum of the currents delivered by sub-cells 23 and 25. The operating point of the tunnel diode is located in portion 51 of characteristic curve I(V). The tunnel diode then operates in a so-called “linear” and “on” regime. It is conductive and acts as a resistor of a very low value. Tunnel diode 27 enables the carriers to pass between sub-cells 23 and 25.

FIG. 3B is a section view illustrating schematically a two-junction solar cell of the type described in relation with FIG. 1 in the case wherein the two sub-cells 23, 25 are connected independently of one another. In this case the term used is operation in “multi-terminal” mode.

In the multi-terminal operating mode, a potential difference V_{AB} is applied between electrodes 35(A) and 41(B) to polarise sub-cell 25, and a potential difference V_{CD} is applied between electrodes 43(C) and 39(D) to polarise sub-cell 23. Since layers 31 and 29 of the tunnel diode, on which contacts B and C are respectively made, are superposed without any intermediate insulator, the current conduction between layers 31 and 29 of the tunnel diode must be minimised.

To this end, a carefully chosen potential difference V_{BC} is first applied between electrodes 41 and 43, i.e. at the terminals of the tunnel diode. Polarisation V_{BC} is chosen such that it is close to polarisation Vv for which current I flowing through the tunnel diode is minimal (equal to value Iv). The tunnel diode then operates in a so-called “off” regime. Tunnel diode 27 is no longer conductive, but is almost insulative. Sub-cells 23 and 25 then operate independently of one another.

In addition, to optimise the power delivered by the solar cell, the optimum polarisation point of each sub-cell may be determined, i.e. potential difference Vmax to be applied between the electrodes associated with each sub-cell such that the power delivered by each sub-cell is maximum.

To find the optimum polarisation point of sub-cell 25, a potential difference V_{AB} is applied between electrodes 35 and 41. Potential difference V_{AB} is varied, and the current delivered by the sub-cell as a function of this potential difference is measured. From these measurements the power delivered by the sub-cell is calculated as a function of potential difference V_{AB}. Potential difference V_{AB} for which the power delivered by sub-cell 25 is maximum corresponds to optimum polarisation Vmax of sub-cell 25. To find the optimum polarisation point of sub-cell 23, a potential difference V_{CD} is applied between electrodes 43 and 39, and a similar procedure is followed.

One advantage of a solar cell of the type illustrated in FIG. 1 is that it can operate either as a monolithic two-junction solar cell (in monolithic mode, described above in relation with FIG. 3A), or as a multi-terminal two-junction solar cell (in multi-terminal mode, described above in relation with FIG. 3B).

Another advantage of such a solar cell is related to the fact that the operation of each of the sub-cells can be optimised individually, and therefore the overall efficiency of the solar cell can be maximised.

Another advantage of such a solar cell is that it can be manufactured by a manufacturing method which is simple to implement, of the monolithic type.

FIG. 4 is a section view representing schematically a three-junction solar cell according to the invention.

The solar cell includes a stack of three sub-cells 63, 65 and 67, where a tunnel diode 69, 75 is interposed respectively between sub-cells 63 and 65 and between sub-cells 65 and 67. Each tunnel diode 69, 75 includes a stack of two superposed semiconducting layers, 71 and 73, 77 and 79, which are highly doped with opposite conductivity types.

An electrode 35 is in contact with face 28 of the solar cell and preferably does not cover this face completely. An electrode 39 is in contact with face 22 of the solar cell and preferably covers this face completely.

Electrodes 85 and 86 are in contact respectively with layers 73 and 71 of tunnel diode 69, and are electrically isolated from the other layers of the stack. Similarly, electrodes 88 and 89 are in contact respectively with layers 79 and 77 of tunnel diode 75, and are electrically isolated from the other layers of the stack. Electrodes 85 and 86 are intended to polarise respectively layers 73 and 71 of tunnel diode 69, and electrodes 88 and 89 are intended to polarise respectively layers 79 and 77 of tunnel diode 75.

Sub-cell 67 is intended to be polarised by electrodes 35 and 88. Sub-cell 65 is intended to be polarised by electrodes 89 and 85. Sub-cell 63 is intended to be polarised by electrodes 39 and 86.

Like the two-junction solar cell illustrated in FIG. 1, the three-junction solar cell illustrated in FIG. 4 can operate either in monolithic mode or in multi-terminal mode.

In monolithic mode a potential difference is applied between electrodes 35 and 39 respectively in contact with faces 28 and 22. Electrodes 85, 86, 88, 89 are not connected. Tunnel diodes 69 and 75 are electrically conductive, and sub-cells 63, 65, 67 and tunnel diodes 69, 75 are connected in series.

In multi-terminal mode a potential difference roughly equal to polarisation Vv of tunnel diode 75 is applied between contacts 88 and 89 and a potential difference roughly equal to polarisation Vv of tunnel diode 69 is applied between contacts 85 and 86, such that the current flowing through tunnel diodes 75 and 69 is minimal. Sub-cells 63, 65, 67 are connected independently of one another by application of a potential difference between the electrodes which are associated with them. The three sub-cells can be connected independently of one another and simultaneously. It is also possible, for example, to connect a single one of the three sub-cells simultaneously, or two of the three sub-cells simultaneously.

FIG. 5 is a section view representing schematically a variant of a three-junction solar cell according to the invention. The elements common with those of FIG. 4 are designated by the same references.

Compared to the solar cell illustrated in FIG. 4, the solar cell illustrated in FIG. 5 does not include contacts intended to polarise layers 71 and 73 of tunnel diode 69. Tunnel diode 69 is electrically conductive and sub-cells 63 and 65 are connected in series. This embodiment can be chosen when sub-cells 63 and 65 are to be current-aligned.

Sub-cell 67 can be connected in series with the assembly of sub-cells 63 and 65, or connected independently of the assembly of sub-cells 63 and 65 by means of polarisation contacts 88 and 89 of layers 79 and 77 of tunnel diode 75.

To connect sub-cell 67 in series with the assembly of sub-cells 63 and 65, a potential difference is applied between electrodes 35 and 39, and electrodes 88 and 89 are not connected. Tunnel diode 75 is then electrically conductive. The solar cell operates in monolithic mode.

To connect sub-cell 67 independently of the assembly of sub-cells 63 and 65, a potential difference roughly equal to polarisation Vv of tunnel diode 75 is applied between electrodes 88 and 89 such that the current flowing through tunnel diode 75 is minimal. Sub-cell 67 is polarised by application of a potential difference between electrodes 35 and 88, and the assembly of sub-cells 63 and 65 is polarised by application of a potential difference between electrodes 89 and 39. The solar cell operates in a mixed mode between the monolithic and multi-terminal modes. It is possible for only the assembly of sub-cells 63 and 65 to be polarised, or for only sub-cell 67 to be polarised.

FIG. 6 is a section view representing schematically a variant of a two-junction solar cell according to the invention. The elements common with those of FIG. 1 are designated by the same references.

Electrodes 41 and 43, which are respectively in contact with layers 31 and 29 of tunnel diode 27, are not positioned on the side of face 28 intended to be exposed to the light radiation as in the solar cell illustrated in FIG. 1, but on the side of face 22. Unrepresented conductive vias may also be included through the stack of the sub-cells to return the connections of electrode 35 towards face 22 of the solar cell.

A solar cell of the type illustrated in FIGS. 1 and 4-6 may include a stack of n sub-cells (where n is an integer greater than or equal to 2), where a tunnel diode 27, including two superposed layers 29, 31 which are highly doped with opposite conductivity types, is interposed between two adjacent sub-cells. In such a solar cell, two electrodes 35, 39 are respectively in contact with faces 28, 22 positioned at the ends of the stack. For at least one tunnel diode 27, two other electrodes 41 and 43 are respectively in contact with layers 31 and 29 of the tunnel diode. Electrodes 41, 43 are not in direct contact with the sub-cells. Electrodes 41 and 43 are intended to polarise respectively layers 31 and 29 of tunnel diodes 27.

According to one embodiment, each tunnel diode is associated with two electrodes 41, 43, enabling each sub-cell to be polarised independently of the other sub-cells.

The sub-cell in the upper level of the stack (level n) is intended to be polarised by electrode 35 and by electrode 41 in contact with upper layer 31 of the tunnel diode separating this sub-cell from the sub-cell of level n−1. The sub-cell in the lower level of the stack (level 1) is intended to be polarised by electrode 39 and by electrode 43 in contact with lower layer 29 of the tunnel diode separating this sub-cell from the sub-cell of level 2.

Each sub-cell of level i included between 2 and n−1 is intended to be polarised by electrode 43 in contact with lower layer 29 of the tunnel diode separating the sub-cell of level i from the sub-cell of level i+1, and by electrode 41 in contact with upper layer 31 of the tunnel diode separating the sub-cell of level i from the sub-cell of level i−1.

By this means, each sub-cell may be associated with two electrodes enabling it to be polarised independently of the other sub-cells, for operation in multi-terminal mode. The different sub-cells can be connected independently of one another simultaneously. By application of a potential difference roughly equal to polarisation Vv of the tunnel diode between contacts 41, 43, the current flowing through each tunnel diode is minimised so as to allow operation of each sub-cell independent of that of the other sub-cells.

As a variant, the solar cell may include tunnel diodes which are not associated with polarisation contacts 41, 43. These tunnel diodes are then electrically conductive. By this means assemblies of sub-cells connected in series are obtained.

FIG. 7 is a diagram illustrating a method of using a multi-junction solar cell according to the invention. In the description of FIG. 7 below, the term “sub-cell” also means an assembly of sub-cells connected in series (such as, for example, the assembly of sub-cells 63 and 65 of the solar cell illustrated in FIG. 5). The current delivered by each sub-cell, independently of the other sub-cells, is measured (“MES”, step 101). The sub-cells are connected one after the other for a given incident radiation. For the different sub-cells, the same potential difference is applied between the electrodes associated with them to perform the current measurement.

The values obtained of the current delivered by the different sub-cells are compared (“ALIGN?”, step 103).

If the currents delivered by the different sub-cells are all equal, it is said that the sub-cells are current-aligned. The multi-junction solar cell is then connected such that it operates in monolithic mode (“ML”, step 105).

To this end, for each tunnel diode 27 associated with electrodes 41 and 43 respectively in contact with layers 31 and 29, electrodes 41 and 43 are not connected, and the tunnel diodes are electrically conductive. A potential difference is applied between electrodes 35 and 39 respectively in contact with faces 28 and 22 of the solar cell. The sub-cells and the tunnel diodes are connected in series. The potential difference applied between electrodes 35 and 39 is advantageously chosen so as to maximise the power delivered by the multi-junction solar cell.

If the currents delivered by the different sub-cells are not all equal the sub-cells are not current-aligned. The multi-junction solar cell is then connected such that it operates in multi-terminal mode (“MT”, step 107). To do so, for each tunnel diode 27 associated with electrodes 41 and 43, a potential difference roughly equal to polarisation Vv of the tunnel diode is applied between electrodes 41 and 43 such that the current flowing through the tunnel diodes is minimal. A potential difference is applied between the electrodes associated with each sub-cell.

It is possible to determine here polarisation point Vv of each tunnel diode and optimum polarisation point Vmax of each sub-cell for which the power delivered by the sub-cell is maximum, as explained above in relation with FIGS. 2, 3A and 3B.

To maximise the power delivered by the solar cell each electrode of the solar cell is advantageously polarised such that the potential difference between electrodes 41, 43 of each tunnel diode is roughly equal to polarisation Vv and such that the potential difference between the electrodes associated with each sub-cell is roughly equal to optimum polarisation Vmax.

In the case of the variant illustrated in FIG. 5, the solar cell includes tunnel diodes which are not associated with polarisation contacts 41, 43 and which are electrically conductive. In multi-terminal mode each assembly of sub-cells connected in series is also advantageously polarised such that it delivers a maximum power output.

One advantage of such a method of using a multi-junction solar cell is that the power delivered by the solar cell can be optimised even when the sub-cells do not all deliver the same current.

Another advantage of such a method of using a multi-junction solar cell is that if one of the sub-cells or an external element such as a concentration lens has degraded performance this has no impact on the performance of the solar cell since the sub-cells are then connected in multi-terminal mode.

Another advantage of such a method of using a multi-junction solar cell is that it is not necessary to manufacture the solar cell such that all the sub-cells deliver the same current. This results in a more simple method for manufacturing such a solar cell.

One embodiment of a method of using a multi-junction solar cell such as the one illustrated in FIG. 7 consists in repeating, for example at regular time intervals, steps 101 and 103 of checking of the current alignment of the different sub-cells, followed by step 105 of connection of the solar cell in monolithic mode or step 107 of connection of the solar cell in multi-terminal mode. Thus, if the performance of one or more sub-cells is degraded in the course of using the solar cell, or if the properties of the concentration lens are degraded over a portion of the solar spectrum, or if the real solar spectrum is not in accordance with the solar spectrum used for the design of the solar cell, leading to a current misalignment of the sub-cells, the solar cell changes from monolithic operating mode to multi-terminal operating mode. This results in an optimised efficiency of the solar cell.

With each repetition of step 107 polarisation point Vv of each tunnel diode and optimum polarisation point Vmax of each sub-cell may be determined once again.

One variant of a method of using a multi-junction solar cell of the type illustrated in FIG. 7 consists in using an operating mode of the solar cell which is mixed between the monolithic and multi-terminal modes. After step 103 of comparison of the currents delivered by the different sub-cells, if the currents delivered by the different sub-cells are not all equal the adjacent sub-cells of the stack which are current-aligned are connected in series (monolithic mode), and the sub-cells which deliver a current less than the current delivered by the other sub-cells are connected independently, in multi-terminal mode.

A device for testing a multi-junction solar cell according to the invention is described below, which enables the method of using a multi-junction solar cell described above in relation with FIG. 7 to be implemented. Here again, as in the description of FIG. 7, the term “sub-cell” designates equally an assembly of sub-cells connected in series.

The test device includes current measuring means, enabling the current delivered by each sub-cell to be measured as a function of the potential difference applied between the electrodes which are associated with it. These current measuring means may be connected to means for comparing the currents delivered by the different sub-cells.

Means also enable the solar cell to be connected such that it operates in monolithic mode if the currents delivered by the different sub-cells are equal, and such that it operates in multi-terminal mode if the currents delivered by the different sub-cells are not all equal.

The above current measuring means may also enable the current flowing through each tunnel diode 27 to be measured as a function of the potential difference applied between electrodes 41, 43 of the tunnel diode.

Analysis means allow, according to these current measurements, to determine, for each tunnel diode, the potential difference Vv to be applied between electrodes 41, 43 such that the current flowing through the tunnel diode is minimal.

Calculation means enable the power delivered by each sub-cell to be calculated as a function of its polarisation, from measurements of the current delivered by the sub-cell as a function of its polarisation.

Means, for example the above analysis means, also enable optimum polarisation Vmax of each sub-cell for which the power delivered by the sub-cell is maximum to be determined, from calculations of the power delivered by each sub-cell as a function of its polarisation.

Means may be provided to calculate the potential to be applied to each electrode of the solar cell such that the potential difference between electrodes 41, 43 of each tunnel diode is roughly equal to polarisation Vv of the tunnel diode, and such that the potential difference between the electrodes associated with each sub-cell is roughly equal to optimum polarisation Vmax of the sub-cell.

The test device may include a computer or a calculator or a measuring system allowing calculations or measurements of currents, and/or of potential differences, and/or of potentials and/or of power outputs presented above.

One method which can be implemented to produce a multi-junction solar cell of the type illustrated in FIG. 1 is described below.

FIGS. 8A-8D are section views representing schematically successive steps of a method for manufacturing a two-junction solar cell according to the invention.

For the sake of simplification the method is described in the specific context of a two-junction solar cell. Such a manufacturing method can of course be used to form a solar cell with n junctions (where n is an integer greater than or equal to 2), where a tunnel diode is interposed between two adjacent sub-cells.

FIG. 8A represents a stack of two sub-cells 123 and 125, where a tunnel diode 127 is interposed between sub-cells 123 and 125. Each sub-cell 123, 125 consists of a stack of different semiconducting layers forming a PN junction. Tunnel diode 127 includes a tunnel junction consisting of two superposed semiconducting layers 129 and 131, which are very highly doped with opposite conductivity types. Face 128 of the stack is, for example, intended to be exposed to the light radiation, and face 122 of the stack is opposite this face.

The different layers of the stack of sub-cell 123, of tunnel diode 127 and of sub-cell 125 have, for example, been formed successively by epitaxial growth. The lower layer of sub-cell 123 has, for example, been used as a substrate for the epitaxial growth. Layers of the stack may possibly have been formed by methods for transferring thin layers onto a receiving substrate.

FIG. 8B illustrates the formation of an opening 133 in sub-cell 125, so as to expose a portion 132 of the upper surface of layer 131 of tunnel diode 127. To do so, the portions of sub-cell 125 which it is not desired to eliminate are previously protected. Opening 133 is then formed by an etching method, for example by a method of anisotropic etching, for example by plasma etching. Opening 123 is, for example, formed at the edge of the solar cell as it is formed.

FIG. 8C illustrates the formation of another opening 134 in sub-cell 125 and in layer 131 of tunnel diode 127, so as to expose a portion 130 of the upper surface of layer 129 of tunnel diode 127. To do so, the portions of sub-cell 125 and of layer 131 which it is not desired to eliminate are previously protected. Opening 134 is then formed by an etching method, for example by a method of anisotropic etching. Opening 134 is, for example, formed at the edge of the solar cell as it is formed, at a distance from opening 133.

FIG. 8D illustrates the formation of conductive contacts intended to polarise the solar cell.

A conductive contact (or electrode) 135 is formed on face 128 of the stack, preferably so as to cover face 128 only partly. To do so, a conductive layer, for example made of a conductive material or of a doped semiconductor material, is formed on the face 128. Patterns are then formed in the conductive layer, for example by photolithography followed by etching, so as to define conductive tracks positioned at a distance from one another. Contact 135 is, for example, formed of conductive lines parallel to one another.

A conductive contact (or electrode) 139 is formed on face 122 of the stack, preferably so as to cover face 122 fully. To do so, a continuous conductive layer, for example made of a conductive material or of a doped semiconductor material, is formed on face 122, for example at the same time as the conductive layer of contact 135.

Contacts 135 and 139 are intended to polarise respectively faces 128 and 122 of the solar cell.

A conductive contact (or electrode) 141 is formed on the exposed portion 132 of layer 131 of tunnel diode 127. Contact 141 is formed at a distance from sub-cell 125. A conductive contact (or electrode) 143 is formed on the exposed portion 130 of layer 129 of tunnel diode 127. Contact 143 is formed at a distance from sub-cell 125, and from layer 131 of the tunnel diode. Prior to the formation of contacts 141 and 143, the edges of openings 133 and 134 are, for example, covered with an insulating material intended to insulate contact 141 from sub-cell 125 and contact 143 from sub-cell 125 and from layer 131. Contacts 141 and 143 are intended to polarise respectively layers 131 and 129 of tunnel diode 127.

By this means a two-junction solar cell of the type illustrated in FIG. 1 is obtained.

One advantage of a method of manufacturing a multi-junction solar cell of the type described in relation with FIGS. 8A-8D is that it is simple to implement. Indeed, such a method uses steps which are commonly used in the course of methods for manufacturing microelectronic components.

According to one variant of the method illustrated in FIGS. 8A-8D, the order of the steps illustrated respectively in FIGS. 8B and 8C may be reversed.

According to another variant of the method illustrated in FIGS. 8A-8D, openings 133 and 134 are formed from face 122, not from face 128. In this case, the formation of opening 133 allows, for example, a portion of the lower surface of layer 131 of tunnel diode 127 to be exposed, and the formation of opening 134 allows a portion of the lower surface of layer 129 of the tunnel diode to be exposed. The connections of contacts 141 and 143 of the tunnel diode are then turned back towards face 122 of the solar cell opposite the face intended to be exposed to the light radiation. By this means a solar cell of the type illustrated in FIG. 6 is obtained. Conductive vias may also be formed through the stack of sub-cells to return the connections of electrode 135 towards face 122 of the solar cell.

According to another variant of the method illustrated in FIGS. 8A-8D, contacts 135, 139, 141, 143 may be formed in the form of conductive vias.

1-27. (canceled)

28. A solar cell comprising:
a stack of at least two sub-cells, wherein a tunnel diode, including first and second superposed layers that are doped with opposite conductivity types, is interposed between two adjacent sub-cells;
a first electrode and a second electrode in contact respectively with one face and an other face of the stack; and
for at least one tunnel diode, a third electrode and a fourth electrode respectively in electrical contact with the first layer and the second layer of the tunnel diode.

29. A solar cell according to claim 28, wherein:
the first electrode is in contact with a face of the stack configured to be exposed to the light radiation; and
the second electrode is in contact with a face of the stack opposite the face configured to be exposed to the light radiation.

30. A solar cell according to claim 29, wherein, for the at least one tunnel diode, the third and fourth electrodes are respectively in contact, or in direct contact, with the first and second layers of the tunnel diode, both either on a side of the face of the stack configured to be exposed to the light radiation or on a side of the face of the stack opposite the face configured to be exposed to the light radiation.

31. A solar cell according to claim 28, wherein, for each tunnel diode, a third electrode and a fourth electrode are respectively in electrical contact with the first layer and the second layer of the tunnel diode.

32. A solar cell according to claim 28, wherein at least two adjacent sub-cells are separated by a tunnel diode, the first layer and the second layer of which are not in contact with any electrode, wherein the at least two adjacent sub-cells form an assembly of sub-cells configured to be connected in series.

33. A solar cell according to claim 28, wherein, for at least one tunnel diode, the tunnel diode also includes first and second conductive barrier layers, positioned on either side of the stack of the first and second layers, respectively in contact with the first layer and with the second layer.

34. A solar cell according to claim 33, wherein the third electrode is in direct contact with the first barrier layer and/or the fourth electrode is in direct contact with the second barrier layer.

35. A method for forming a solar cell, comprising:
a) forming a stack of at least two sub-cells, wherein a tunnel diode, including first and second superposed layers that are doped with opposite conductivity types, is interposed between two adjacent sub-cells;
subsequently, in any order;
b) forming a first electrode and a second electrode respectively in contact with a face of the stack configured to be exposed to the light radiation and with a face of the stack opposite the face configured to be exposed to the light radiation; and
c) for at least one tunnel diode, forming a third electrode and a fourth electrode respectively in electrical contact with the first layer and the second layer of the tunnel diode.

36. A method according to claim 35, wherein, in c), for each tunnel diode, a third electrode and a fourth electrode, in electrical contact respectively with the first layer and the second layer of the tunnel diode, are formed.

37. A method according to claim 36, wherein, in a), the stack of at least two sub-cells with interposition of a tunnel diode is formed by epitaxial growth.

38. A method according to claim 35, further comprising, between a) and c), formation, for at least one tunnel diode, of a first opening and of a second opening, to expose respectively a portion of the first layer and a portion of the second layer of the tunnel diode.

39. A method according to claim 38, wherein the formation, for at least one tunnel diode, of the first and second openings, is performed before b) forming the first and second electrodes.

40. A method according to claim 38, wherein the first and second openings are formed by a method of anisotropic etching.

41. A method according to claim 38, wherein the first and second openings are formed both either from the face of the stack configured to be exposed to the light radiation or from the face of the stack opposite the face configured to be exposed to the light radiation.

42. A method of using a solar cell according to claim 28, comprising:
a) measuring current delivered by each sub-cell or assembly of sub-cells connected in series;
b) comparing the currents delivered by the different sub-cells or assemblies of sub-cells;
c) if the currents delivered by the different sub-cells or assemblies of sub-cells are equal, connecting the solar cell such that it operates in monolithic mode;
c′) if the currents delivered by the different sub-cells or assemblies of sub-cells are not all equal, connecting the solar cell such that it operates in multi-terminal mode.

43. A method of using a solar cell according to claim 42, wherein, for each tunnel diode of which the first layer and the second layer are respectively in contact with a third electrode and a fourth electrode:
in c), the third and fourth electrodes are not connected and the tunnel diode is electrically conductive;
in c′), a potential difference is applied between the third and fourth electrodes such that the current flowing through the tunnel diode is minimal.

44. A method of using a solar cell according to claim 42, wherein, in c), a potential difference is applied between the first and second electrodes such that the power delivered by the solar cell is maximum.

45. A method of using a solar cell according to claim 43, wherein, in c′), for each tunnel diode of which the first layer and the second layer are respectively in contact with a third electrode and a fourth electrode, it is sought to determine potential difference to be applied between the third and fourth electrodes for the current flowing through the tunnel diode to be minimal.

46. A method of using a solar cell according to claim 42, wherein, in c′), for each sub-cell or assembly of sub-cells connected in series, it is sought to determine optimum polarization of the sub-cell or of the assembly of sub-cells for the power delivered by the sub-cell or by the assembly of sub-cells to be maximum.

47. A method of using a solar cell according to claim 46, wherein, in c′), each electrode of the solar cell is polarized such that each sub-cell or assembly of sub-cells is polarized at the optimum polarization.

48. A method of using a solar cell according to claim 42, further comprising d) repeating a) to c) or a) to c′).

49. A method of using a solar cell according to claim 48, wherein d) is repeated at regular time intervals.

50. A method of using a solar cell according to claim 28, comprising:
a) measuring current delivered by each sub-cell;
b) comparing the currents delivered by the different sub-cells;
c) if the currents delivered by the different sub-cells are equal, connecting the solar cell such that it operates in monolithic mode;
c′) if the currents delivered by the different sub-cells are not all equal:
connecting the adjacent sub-cells which deliver the same current in monolithic mode;
connecting the other sub-cells in multi-terminal mode.

51. A device for testing a solar cell according to claim 28, comprising:
a measuring system configured to determine current delivered by each sub-cell or assembly of sub-cells connected in series;
a comparator configured to compare the currents delivered by the different sub-cells or assemblies of sub-cells; and
connections for connecting the solar cell such that it operates in monolithic mode if the currents delivered by the different sub-cells or assemblies of sub-cells are equal, and such that it operates in multi-terminal mode if the currents delivered by the different sub-cells or assemblies of sub-cells are not all equal.

52. A device for testing a solar cell according to claim 51, further comprising:
a first analysis calculator configured to seek, for each tunnel diode of which the first layer and the second layer are respectively in contact with a third electrode and a fourth electrode, the potential difference to be applied between the third and fourth electrodes for the current flowing through the tunnel diode to be minimal;
a calculator configured to calculate the power delivered by each sub-cell or assembly of sub-cells as a function of its polarization;
a second analysis calculator configured to seek, for each sub-cell or assembly of sub-cells, optimum polarization of the sub-cell or of the assembly of sub-cells for which the power delivered by the sub-cell or by the assembly of sub-cells is maximum; and
the device being configured to determine the potential to be applied to each electrode of the solar cell, such that the current flowing through each tunnel diode is minimum, and such that the power delivered by each sub-cell or assembly of sub-cells is maximum.
